(19) United States
(12) Patent Application Publication
(10) Pub. No.: US 2025/0114982 A1
(43) Pub. Date: Apr. 10, 2025

(54) METHOD FOR MANUFACTURING A CONNECTION FILM

(71) Applicant: DEXERIALS CORPORATION, Shimotsuke-shi, Tochigi (JP)

(72) Inventors: Saori SUGIOKA, Tochigi (JP); Kosuke ASABA, Tochigi (JP)

(73) Assignee: DEXERIALS CORPORATION, Shimotsuke-shi, Tochigi (JP)

(21) Appl. No.: 18/694,783

(22) PCT Filed: Sep. 27, 2022
(86) PCT No.: PCT/JP2022/035844

§ 371 Date: Mar. 22, 2024

(30) Foreign Application Priority Data
Sep. 29, 2021 (JP) 2021-159766
Sep. 27, 2022 (JP) 2022-153351

(51) Int. Cl. B29C 33/68

(52) U.S. Cl. CPC B29C 33/68

(57) ABSTRACT

A method for manufacturing a connection film achieves high productivity. The method includes printing an adhesive in a predetermined shape on a mold release film, and forming a connection film of a predetermined shape on the mold release film. A plurality of connection films of the predetermined shape are formed in the width direction of the mold release film, the mold release film is cut in the longitudinal direction at a predetermined width, a plurality of mold release films of the predetermined width are connected in the longitudinal direction, and the connected mold release films of the predetermined width are wound around a winding core. This enables high productivity.

### TECHNICAL FIELD

This technology relates to a method for manufacturing a connection film for connecting electronic components. This application claims priority based on Japanese Patent Application No. 2021-159766 filed in Japan on Sep. 29, 2021 and Japanese Patent Application No. 2022-153351 filed in Japan on Sep. 27, 2022, which are hereby incorporated by reference.

### BACKGROUND ART

In recent years, smartphones and other mobile devices have become more densely packed with components, creating space constraints within the case. In particular, in camera modules, cameras (image capture unit, image sensor) are becoming larger and more diverse, requiring more space for embedded parts.

FIGS. 24A and 24B are schematic perspective views of an example of a camera module substrate, in which FIG. 24A is a schematic perspective view of a substrate with a recess (cavity) on the mounting surface and FIG. 24B is a schematic perspective view of a substrate with a polygonal mounting surface. As shown in FIGS. 24A and 24B, in order to provide a space, measures are taken to eliminate excess portions of the board or FPCs (Flexible Printed Circuits), such as by cutting off corners 101 and providing recesses 102 on the mounting surface.

It is difficult to use ordinary connection films with substrates having complex shapes. One mounting method for substrates having complex shapes is, e.g., to apply conductive paste using a dispenser, but it is difficult to control positional accuracy, overflow, and thickness uniformity, making the conductive connection unstable. Application by using a dispenser is also difficult because it takes too much time in the process to reduce the yield.

In addition, Patent Literature 1 discloses a method of individualizing the connection film by half-cutting the support film and removing unnecessary connection film portions. However, the technology described in Patent Literature 1 increases material loss and the number of processes, and there is still room for improvement in the productivity of connection films.

### CITATION LIST

### Patent Literature

Patent Literature 1: JP 2020-198422 A

### SUMMARY OF INVENTION

### Technical Problem

The present technology is proposed in view of such existing circumstances, and provides a method for manufacturing a connection film capable of improving productivity.

### Solution to Problem

The method for manufacturing a connection film according to the present technology includes printing an adhesive in a predetermined shape on a mold release film, and forming a connection film of a predetermined shape on the mold release film.

### Advantageous Effects of Invention

This technology reduces material loss and the number of processes, thereby achieving good productivity of the connection film.

### BRIEF DESCRIPTION OF DRAWINGS

FIG. 1 is a schematic perspective view of an example of a printing step in a method for manufacturing a connection film.

FIG. 2 is a schematic perspective view of an example of a drying step in the method for manufacturing a connection film.

FIG. 3 is a schematic perspective view of an example of a temporary pasting step in which a connection film is temporarily pasted to the substrate.

FIGS. 4A and 4B are plan views illustrating a cutting step of cutting a connection film of a predetermined shape, in which FIG. 4A is a plan view illustrating the cutting step to obtain a linear-shaped connection film, and FIG. 4B is a plan view illustrating the cutting step to obtain an individual-piece-shaped anisotropic connection film.

FIGS. 5A and 5B are plan views illustrating a cutting step that does not cut the connection film of a predetermined shape, in which FIG. 5A is a plan view illustrating the cutting step to obtain a linear-shaped connection film, and FIG. 5B is a plan view illustrating the cutting step to obtain an individual-piece-shaped anisotropic connection film.

FIG. 6 is a plan view illustrating Manufacturing Example 1 of a connection film with a width narrower than the slit width.

FIG. 7 is a plan view of Manufacturing Example 2 of a connection film with a width narrower than the slit width.

FIGS. 8A and 8B schematically illustrate the connection film laminate manufactured in Manufacturing Example 2, in which FIG. 8A is a plan view and FIG. 8B is a cross-sectional view.

FIG. 9A is a plan view of one example of a connection film laminate manufactured in Manufacturing Example 2, and FIG. 9B is a plan view of another example of a connection film laminate manufactured in Manufacturing Example 2.

FIG. 10 is a plan view illustrating another manufacturing example of a connection film.

FIG. 11 is a schematic perspective view of a film wound body.

FIG. 12 is a plan view of a mounting surface of a camera module.

FIG. 13 is a cross-sectional view taken along cut line II-II shown in FIG. 12.

FIG. 14 is a plan view of a unit area of a film structure.

FIG. 15 is a cross-sectional view taken along cut line IV-IV shown in FIG. 14.

FIG. 16 is a cross-sectional view illustrating an pasting step of pasting a connection film to a camera module.

FIG. 17 is a cross-sectional view of a state in which a base material is peeled off from a connection film in the pasting step.

FIG. 18 is a cross-sectional view of a mounting step in which a flexible printed circuit is mounted on a camera module.

FIG. 19 is a cross-sectional view of a connection process in which terminals of a camera module are connected to terminals of a flexible printed circuit via a connection film.

FIG. 20 is a cross-sectional view of a connection structure in which a camera module is mounted.

FIG. 21 is a cross-sectional view of a configuration example of a connection structure in which a camera module is mounted.

FIG. 22 is a plan view illustrating the manufacturing of an anisotropic conductive film in an example.

FIG. 23 is a plan view of the manufacturing of an anisotropic conductive film in a conventional example.

FIGS. 24A and 24B are schematic perspective views of an example of a camera module substrate, in which FIG. 24A is a schematic perspective view of a substrate with a recess (cavity) on the mounting surface, and FIG. 24B is a schematic perspective view of a substrate with a polygonal mounting surface.

### DESCRIPTION OF EMBODIMENTS

Embodiments of the invention will be described in detail in the following order with reference to the drawings.
1. METHOD FOR MANUFACTURING CONNECTION FILM
2. FILM WOUND BODY
3. METHOD FOR MANUFACTURING CONNECTION STRUCTURE
4. EXAMPLES

### 1. Method for Manufacturing a Connection Film

A method for manufacturing a connection film according to the present embodiment includes printing an adhesive in a predetermined shape on a mold release film, and forming a connection film of a predetermined shape on the mold release film. Compared to forming a connection film of a predetermined shape by cutting off unnecessary portions, this method reduces material loss and the number of processes to achieve good productivity of the connection film. This also prevents the strength of the mold release film from deteriorating due to cutting.

Connection films are used to connect various electronic components, and includes filler-containing films, conductive films such as anisotropic conductive films (ACF) and isotropic conductive films, and non conductive film (NCF).

Printing methods include screen printing using a plate (screen mask) and inkjet printing in which adhesive is sprayed and applied. Screen printing is suitable for adhesives (ADH) with insulating binders, as well as for paste adhesives with or without solvents, offering a high degree of freedom in the design and selection of adhesive components, while inkjet printing allows patterning directly from data without the need for plates. Screen or inkjet printing can be selected depending on the base material, adhesive properties, and tact time. In the following, screen printing is used as an example.

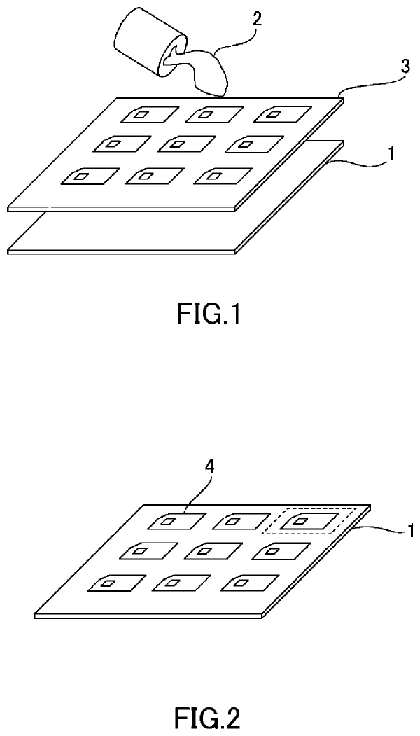

FIG. 1 is a schematic perspective view of an example of a printing step in a method for manufacturing a connection film. As shown in FIG. 1, in the printing step, adhesive 2 is passed through the mesh of a screen mask 3 by pressure with a squeegee or the like, and printed (applied) on a mold release film 1.

The mold release film 1 is a base material that has been release treated with silicone resin, e.g., as described below. Examples of the base material may include PET (poly ethylene terephthalate), OPP (oriented polypropylene), PMP (poly-4-methylpentene-1), and PTFE (polytetrafluoroethylene), among others.

The adhesive 2 can be selected from insulating binders such as thermosetting type, light-curing type, light-thermal combination curing type, and hot-melt type, depending on the purpose. The adhesive 2 may also contain fillers such as conductive particles in the insulating binder.

The screen mask 3 is a plate made of a screen mesh woven with synthetic fibers such as polyester or stainless steel and various metal fibers. If the adhesive 2 contains conductive particles, the mesh may be larger than the maximum diameter of the conductive particles.

FIG. 2 is a schematic perspective view of an example of a drying step in the method for manufacturing a connection film. As shown in FIG. 2, in the drying step, the adhesive 2 of a predetermined shape is dried to form a connection film 4 of a predetermined shape on the mold release film 1. The drying process is preferably carried out by means of an oven or a drier. In the printing and drying steps, it is preferable to form multiple connection films of a predetermined shape in the width direction of the mold release film 1. This enables efficient production of long films as described below.

To form a filler-containing film or conductive film of a predetermined shape on the mold release film 1, an adhesive containing filler or conductive particles may be printed in a predetermined shape, or a filler or conductive particles may be placed at predetermined positions in the film surface view on a connection film of a predetermined shape formed by printing an insulating binder in a predetermined shape. The placement may be intentionally random or in a regular pattern. The methods for placement may include transfer methods. The transfer methods may include, e.g., adhering conductive particles to a micro-adhesive layer of a transfer material, and then placing the conductive-particle adhered surface of the transfer material over the connection film of a predetermined shape and applying pressure to transfer the conductive particles onto the connection film of a predetermined shape. The transfer method is not limited to this. Also, placement methods other than the transfer method are not excluded.

Thus, by uniformly applying the adhesive on the mold release film by printing in a shape that matches the specific design, it is possible to efficiently produce a connection film that can be applied to substrates having complex shapes.

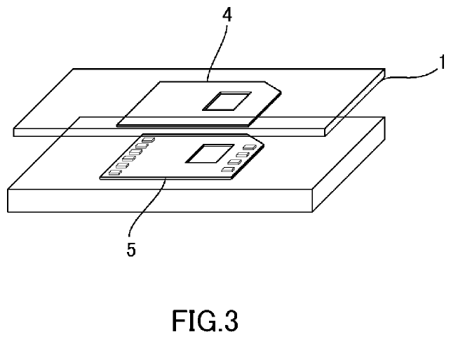

FIG. 3 is a schematic perspective view of an example of a temporary pasting step in which a connection film is temporarily pasted to the substrate. As shown in FIG. 3, by temporarily pasting (attaching) the connection film 4 of a predetermined shape onto the substrate 5 while aligning it, the connection film 4 can be mounted without protruding from the substrate 5, which enables stable production of mounted bodies. In addition, by providing an alignment mark (e.g., by printing on the mold release film 1), which is necessary when temporarily pasting the connection film 4, the accuracy of positioning can be further improved.

### Modification 1

As shown in FIGS. 1 and 2, by forming a plurality of connection films 4 of a predetermined shape in the width direction of the mold release film 1, connection films 4 of a predetermined shape can be efficiently manufactured on a long mold release film 1. In other words, the aforementioned method for manufacturing a connection films preferably further includes a cutting step of cutting the mold release film 1 in a predetermined width in a longitudinal direction, a connecting step of connecting a plurality of mold release films 1 of a predetermined width in a longitudinal direction, and a winding step of winding the connected mold release films 1 of a predetermined width around a winding core. This enables efficient production of a film wound body.

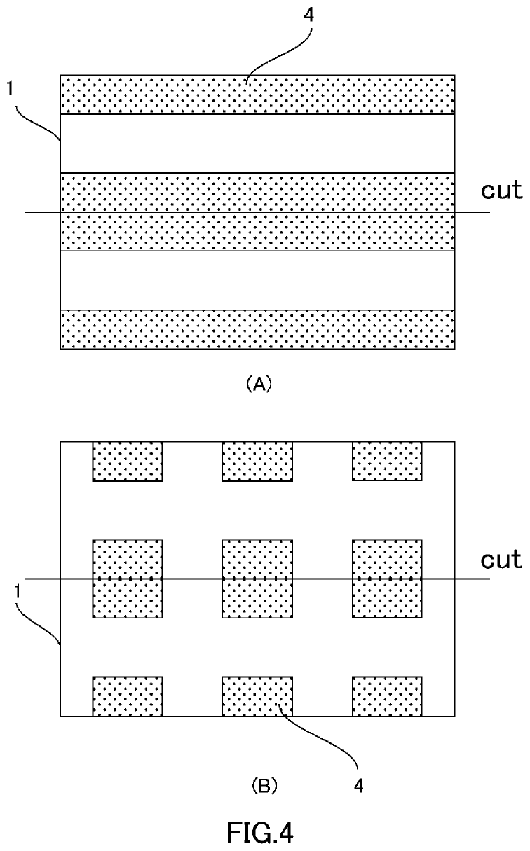

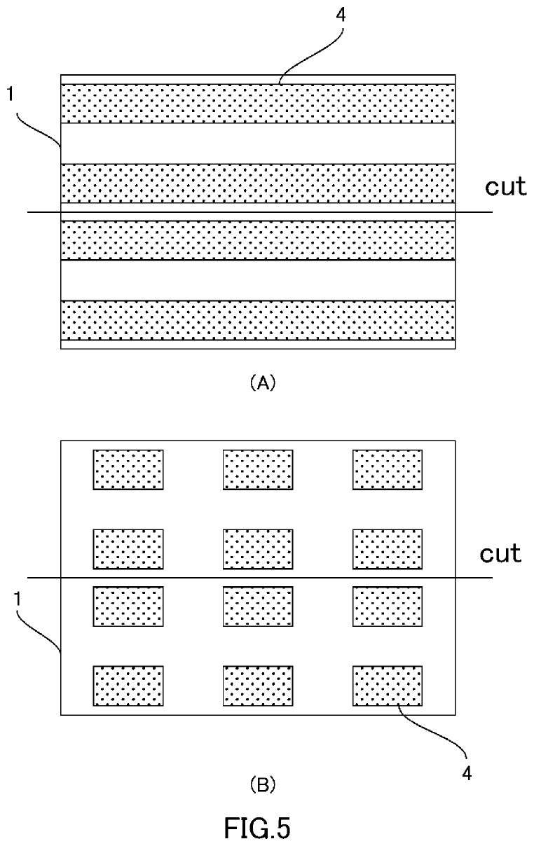

The cutting step in a modification will now be described using FIGS. 4 and 5. FIGS. 4A and 4B are plan views illustrating a cutting step of cutting a connection film of a predetermined shape, in which FIG. 4A is a plan view illustrating the cutting step to obtain a linear-shaped connection film, and FIG. 4B is a plan view illustrating the cutting step to obtain an individual-piece-shaped connection film.

As shown in FIGS. 4A and 4B, in the cutting step, the connection film 4 of a first shape may be cut together with the mold release film 1 to form the connection film 4 of a second shape that is ½ the width of the first shape. Multiple of these may be provided in the width direction of one original sheet role. The connection film 4 cut from the connection film of the predetermined shape is effective for mounting electronic components adjacent to each other, because the side of the long mold release film overlaps the side of the connection film.

FIGS. 5A and 5B are plan views illustrating a cutting step that does not cut the connection film of a predetermined shape, in which FIG. 5A is a plan view illustrating the cutting step to obtain a linear-shaped connection film, and FIG. 5B is a plan view illustrating the cutting step to obtain an individual-piece-shaped connection film.

As shown in FIGS. 5A and 5B, in the cutting step, only the mold release film 1 may be cut without cutting the connection film of a predetermined shape to form the connection film 4 of a predetermined shape. In the connection film 4 in which only the mold release film 1 is cut, the side of the long mold release film does not overlap with the side of the connection film, thus it is possible to prevent a portion of the connection film from protruding from the side when, for example, a long film is wound around a winding core.

The side of the connection film 4 may coincide with the side of the mold release film 1 (the connection film 4 and the mold release film 1 may be slit at the same time), or the connection film 4 may be accommodated inside the mold release film 1. In this embodiment, the connection film 4 is formed only by printing, but the mold release film 1 may have a cut surface along the side thereof. In the cut surface along the side of the mold release film 1, the side of the connection film 4 approximately coincides with the side of the mold release film 1, as described above. When the connection film 4 is formed by printing, the resin edge of the connection film 4 has a raised or scuffed edge on the inside of the mold release film 1. When the connection film 4 is formed by printing, this can be confirmed by the fact that the side of the resin of the connection film 4 is not straight in relation to the side of the mold release film 1. Scuffing refers to the appearance peculiar to printing, such as the side of the connection film 4 appearing meandering when viewed in plan view, or the uneven thickness of the edge. It also has the microscopic characteristics described below.

### Modification 2

A conductive film with a width narrower than a predetermined width can be obtained by forming a rectangular connection film in the longitudinal direction with margins in the width direction of the mold release film and cutting the mold release film in the longitudinal direction at a predetermined width. In particular, with conventional methods such as the half-cut process, it was difficult to produce a connection film with a width of less than 0.5 mm with considerable productivity and length due to the structure of the slitting and half-cutting blade, but by using printing and slitting together, a connection film with a width of less than 0.5 mm can easily be manufactured. This is especially useful when manufacturing in long lengths.

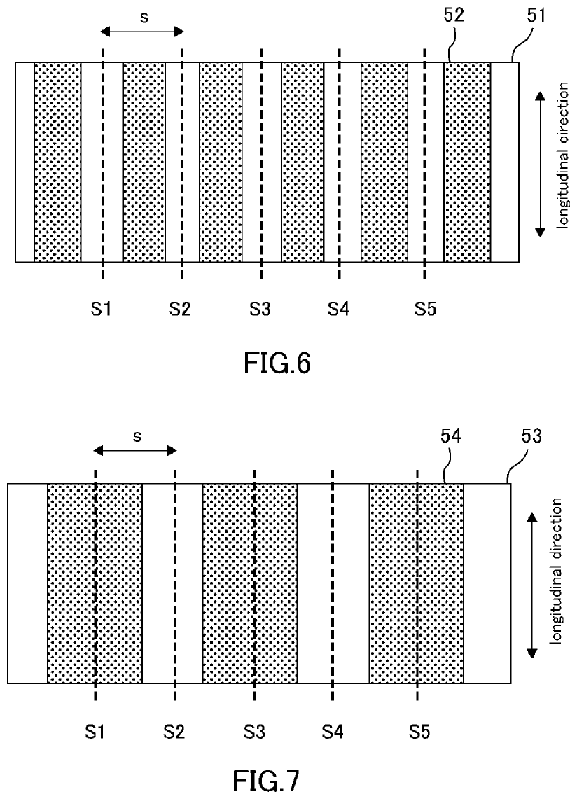

FIG. 6 is a plan view illustrating Manufacturing Example 1 of a connection film with a width narrower than the slit width. As shown in FIG. 6, in Manufacturing Example 1, a connection film 52 is formed by printing adhesive in the longitudinal direction with a width narrower than the slit width s on a mold release film 51, and the mold release film 51 corresponding to margins between the connection films 52 is slit at S1 to S5.

According to Manufacturing Example 1, a connection film narrower than the slit width can be manufactured in a single step by slitting, and a narrower connection film can be manufactured more easily than the conventional method that combines half-cutting and slitting. In Manufacturing Example 1, the film is cut in the longitudinal direction so that both ends of the slit width s correspond to the mold release film 51, which prevents floating and wrinkling from occurring during the slitting process. In addition, since the connection film does not come into contact with the slitting blade, it can be expected to easily avoid adhesion problems. Here, “floating” refers to the state in which the connection film is separated from the mold release film, and “wrinkling” refers to the state in which lines due to, e.g., crimping are observed on the connection film.

FIG. 7 is a plan view of Manufacturing Example 2 of a connection film with a width narrower than the slit width. As shown in FIG. 7, in Manufacturing Example 2, an adhesive is printed in the longitudinal direction at a predetermined width on the mold release film 53, and the mold release film 53 serving as the adhesive and margin is slit at S1 to S5, to form a connection film 54 with a width narrower than the slit width s.

In Manufacturing Example 2, the printing width of the adhesive can be increased up to, e.g., twice the slit width compared to Manufacturing Example 1. In Manufacturing Example 2, the mold release film 53 is cut in the longitudinal direction so that one end of the slit width s is the margin and the other end is the adhesive. Here, the ratio of the width of the connection film 54 to the slit width s is preferably 0.125 or more and 0.75 or less, and more preferably 0.25 or more and 0.6 or less. This prevents floating and wrinkling when slitting. In addition, since the portion where a part of the printing width and a part of the slit width overlap can be adjusted as the width of the adhesive film, it can be expected to obtain an adhesive film with an even narrower width than in Manufacturing Example 1. Thus, by Manufacturing Example 1 and 2, it is possible to obtain a width of the connection film narrower than the width of the mold release film 1 that is slit and wound around a reel.

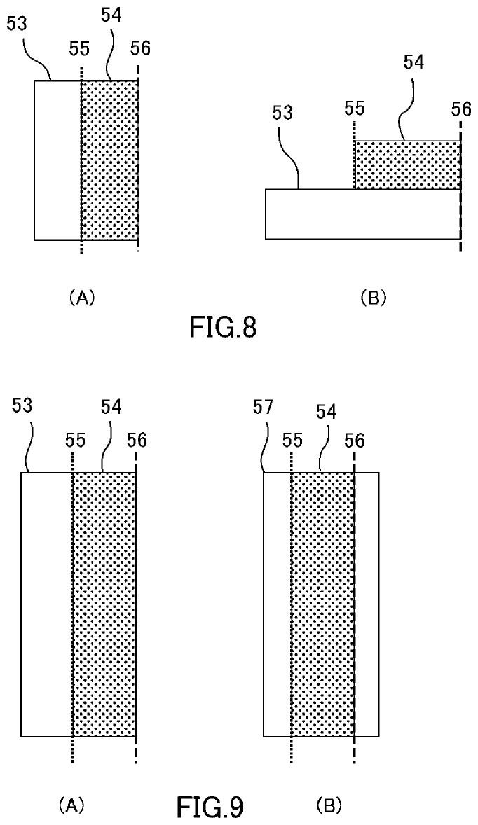

FIGS. 8A and 8B schematically illustrate the connection film laminate manufactured in Manufacturing Example 2, in which FIG. 8A is a plan view and FIG. 8B is a cross-sectional view. As shown in FIGS. 8A and 8B, the side of the connection film 54 manufactured in Manufacturing Example 2 includes a printed side 55 made by printing and a slit side 56 made by slitting. The printed side 55 and the slit side 56 can be observed under a microscope and the differences can be distinguished because, e.g., the printed side has a raised or scuffed resin edge, while the slit side is a cut surface and is relatively sharp. In addition, when contrasted in terms of the thickness of the connection film, the thickness state of the printed edge has a large variation, while the thickness state of the slit edge has a small variation and is stable. Therefore, when compared by observation such as microscopy, it can be seen that the printed edge is relatively rough and the slit edge is relatively smooth.

FIG. 9A, like FIG. 8A, is a plan view of one example of a connection film laminate manufactured in Manufacturing Example 2, and FIG. 9B is a plan view of another example of a connection film laminate manufactured in Manufacturing Example 2. As shown in FIG. 9A, the slit side 56 of the connection film 54 after slitting coincides with the side of the mold release film 53. Here, the connection film 54 after slitting may be rewound onto another mold release film 57. This allows the connection film 54 to be placed in the center of the mold release film 57 in the width direction, as shown in FIG. 9B. By rewinding the connection film in this manner, the position of the mold release film in the width direction can be changed. This can prevent a portion of the connection film from protruding from the side when, e.g., it is lengthened and wound around a winding core.

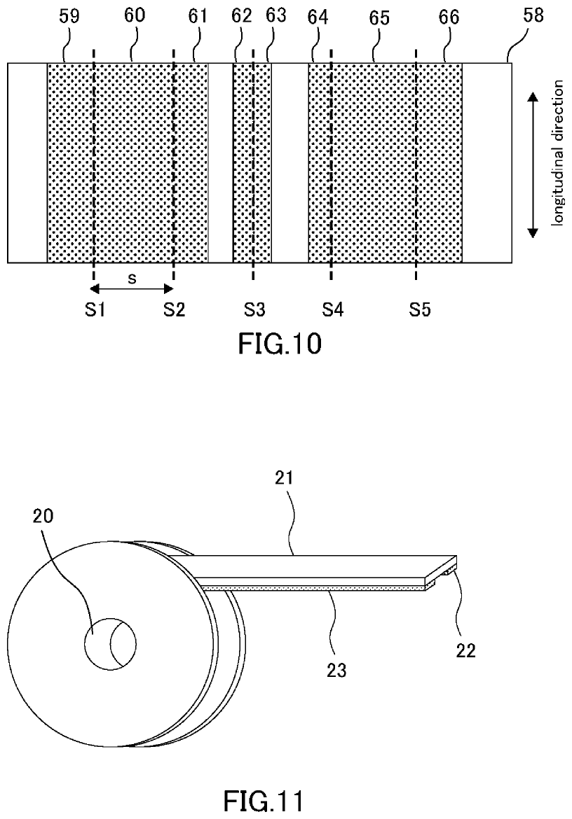

FIG. 10 is a plan view illustrating another manufacturing example of a connection film. As shown in FIG. 10, e.g., adhesive may be printed on a mold release film 58 at a first predetermined width for connection films 59 to 61, a second predetermined width for connection films 62 to 63, and a third predetermined width for connection films 64 to 66 in the longitudinal direction, the mold release film 58 is slit at S1 to S5 to form the connection films 59 to 66 of different widths from a single original sheet role. Furthermore, these connection films of different widths may be half-cut at predetermined lengths to produce individual pieces of connection film of different widths, which may then be transferred to predetermined positions of another mold release film to combine the pieces and form a connection film of a predetermined shape on the mold release film. Although a complex form is described here as an example, even a simpler form or combination of forms can be made by half-cutting and reattaching at predetermined intervals to another mold release film to form individual pieces at the same time as rewinding. By combining printing and slitting in this way, connection films of different widths can be easily manufactured, making the process of producing connection films of different designs and shapes that combine individual pieces simpler than conventional methods, such as half-cut processing, thereby reducing material waste and improving productivity.

### 2. Film Wound Body

FIG. 11 is a schematic perspective view of a film wound body. As shown in FIG. 11, the film wound body consists of a film structure including a tape-shaped base material 21 and connection films 22, 23 formed on the base material 21, wound around a winding core 20. The winding core 20 has a shaft hole into which a rotating shaft for rotating the reel is inserted, and the film structure is wound around the winding core 20 by connecting one end in the longitudinal direction of the film structure. The length of the film structure wound as the film wound body is not particularly limited, but the lower limit of length is 5 m or more, 10 m or more, or 50 m or more, and the upper limit of length can suitably be 5,000 m or less, 500 m or less, 300 m or less, or 100 m or less. For example, if the length is longer than 300 m, it may be made longer by connecting them together.

The base material 21 is a support film made by forming the aforementioned mold release film 1 into a tape shape to support the connection films 22, 23. Examples of the base material 21 may include PET, PMP, and PTFE, among others. The base material 21 can suitably be one in which at least the surface of the connection films 22, 23 is release treated with, e.g., silicone resin.

The thickness of the base material is not particularly limited. The lower limit of the thickness of the base material is preferably 10 μm or more for separation, more preferably 25 μm or more, and still more preferably 38 μm. The upper limit of the thickness of the base material is preferably less than 200 μm, and more preferably less than 100 μm, and still more preferably less than 75 μm because there is concern that excessive pressure may be applied to the connection film if it is too thick. The thickness may be 50 μm or less.

The width of the base material is not particularly limited. The lower limit of the width of the base material may be 0.5 mm or more, preferably 1 mm or more, more preferably 2 mm or more, and still more preferably 4 mm or more in view of rewinding. The upper limit of the width of the base material is preferably 500 mm or less, more preferably 250 mm or less, and still more preferably 120 mm or less, because there is concern that too large a width may be difficult to carry and handle.

As an example of a connection film, an anisotropic conductive film containing conductive particles in an insulating binder will be described below. The lower limit of the thickness of the anisotropic conductive film may be the same as, e.g., the conductive particle diameter and can preferably be 1.3 times or more of the conductive particle diameter, or 2 μm or more, preferably 10 μm or more. The upper limit of the thickness of the anisotropic conductive film can be, e.g., 40 μm or less or twice the conductive particle diameter or less. The anisotropic conductive film may be laminated with adhesive or pressure-sensitive adhesive layers that do not contain conductive particles, and the number of layers and laminated surfaces may be selected according to the target and purpose. The same insulating resins as those used for anisotropic conductive films can be used for the adhesive and pressure-sensitive adhesive layers. Conductive particles may be dispersed or arranged in the resin. If the conductive particles are dispersed in the resin, the individual particles may not be contact with and separated from each other. The thickness of the anisotropic conductive film, like general adhesive or pressure-sensitive adhesive films, is not limited, and the lower limit may be 2 μm or more, preferably 5 μm or more, and the upper limit may be 200 μm or less, preferably 100 μm or less. The anisotropic conductive film may be further laminated with adhesive or pressure-adhesive film. Here, the connection film refers to a film that is provided on a mold release film and can be released as an individual connection film by, for example, adhering it to the object to be connected.

As conductive particles, those used in known anisotropic conductive films may be selected and used as appropriate. For example, examples of the conductive particles may include metal particles such as nickel, copper, silver, gold, and palladium, alloy particles such as solder, and metal-coated resin particles in which the surface of resin particles such as polyamide and polybenzoguanamine is coated with a metal such as nickel. The surface may be insulated to the extent that it does not interfere with conductivity. The surface shape may also have protrusions.

The particle diameter of conductive particles is not particularly limited, but the lower limit of the particle diameter may be 1 μm or more, and 2 μm or more is preferred, and the upper limit of the particle diameter is, e.g., 50 μm or less, and 20 μm or less is further preferred from the viewpoint of the trapping efficiency of conductive particles in the connection structure. The particle diameter of the conductive particles can be the value measured by an image-type particle size distribution meter (as an example, FPIA-3000: Malvern). The number of these particles may be 1,000 or more, preferably 2,000 or more.

For the insulating binder (insulating resin), any known insulating binder can be used. Examples of the curing type may include thermosetting type, photo-curing type, and photo-thermosetting type. Examples may include photo-radical polymerization resin compositions containing (meth) acrylate compounds and photo-radical polymerization initiators, thermal radical polymerization resin compositions containing (meth) acrylate compounds and thermal radical polymerization initiators, thermal cation polymerization resin compositions containing epoxy compounds and thermal cation polymerization initiators, and thermal anion polymerization resin compositions containing epoxy compounds and thermal anion polymerization initiators. Known pressure-sensitive adhesive compositions may also be used. In the case of a hot-melt type, the compositions of JP-A-2014-060025 may be used.

The following is a specific example of a thermal radical polymerization type insulating binder containing a film-forming resin, an elastomer, a (meth) acrylic monomer, a polymerization initiator, and a silane coupling agent. It should be noted that the term (meth) acrylic monomer is meant to include both acrylic monomers and methacrylic monomers.

The film-forming resin is not particularly limited and may include, for example, a phenoxy resin, an unsaturated polyester resin, a saturated polyester resin, a urethane resin, a butadiene resin, a polyimide resin, a polyamide resin, and a polyolefin resin, among others. One film-forming resin may be used alone, or two or more may be used in combination. Among these, the use of phenoxy resin is particularly preferred from the viewpoints of film-forming property, processability, and connection reliability. The phenoxy resin is a resin synthesized from bisphenol A and epichlorohydrin, and may be suitably synthesized or may be a product commercially available. The content of the film-forming resin is not particularly limited, and is preferably, for example, 10 to 60 mass %.

The elastomer is not particularly limited and examples may include a polyurethane resin (polyurethane elastomer), an acrylic rubber, a silicone rubber, and a butadiene rubber, among others.

The (meth) acrylic monomer is not particularly limited, and may be, for example, a monofunctional (meth) acrylic monomer or a bifunctional or multifunctional (meth) acrylic monomer. From the viewpoint of stress relaxation of the polymer, 80 mass % or more of (meth) acrylic monomers in the insulating binder are preferably monofunctional (meth) acrylic monomers.

From the viewpoint of adhesiveness, the monofunctional (meth) acrylic monomer preferably contains a carboxylic acid. The molecular weight of the monofunctional (meth) acrylic monomer having the carboxylic acid is preferably 100 to 500, more preferably 200 to 350. The content of the monofunctional (meth) acrylic monomer having the carboxylic acid in the insulating binder is preferably 3 to 20 mass %, more preferably 5 to 10 mass %.

The polymerization initiator is not particularly limited as long as it can cure the (meth) acrylic monomer at a predetermined temperature at the time of thermocompression bonding, and examples thereof may include an organic peroxide. Examples of the organic peroxide may include lauroyl peroxide, butyl peroxide, benzyl peroxide, dilauroyl peroxide, dibutyl peroxide, peroxydicarbonate, and benzoyl peroxide, among others. These may be used alone or in combination of two or more. The content of the polymerization initiator in the insulating binder is not particularly limited, and is preferably, for example, 0.5 to 15 mass %.

The silane coupling agent is not particularly limited and examples may include, for example, an epoxy-based silane coupling agent, an acrylic silane coupling agent, a thiol-based silane coupling agent, and an amine-based silane coupling agent, among others. The content of the silane coupling agent in the insulating binder is not particularly limited, and is preferably, for example, 0.1 to 5.0 mass %.

### Method for Manufacturing Connection Structure

The method for manufacturing a connection structure of this embodiment includes a pasting step of pasting, from a film structure having a tape-shaped base material and a connection film formed on the base material, a connection film having a predetermined length in the length direction of the base material and a predetermined width in the width direction of the base material to a first electronic component or a second electronic component having a plurality of terminal rows and a connecting step of connecting the terminals of the first electronic component to the terminals of the second electronic component via the connection film, in which the film structure has a non-pasting portion to which the connection film is not pasted other than at the locations corresponding to the plurality of terminal rows in the unit area. This allows mounting electronic components having a plurality of terminal rows on a mounting surface using existing mounting equipment. Also, in the pasting step, the connection film can be pasted in a batch without having to paste the connection film multiple times corresponding to multiple terminal rows.

Here, “unit area” indicates an area that has a predetermined length in the longitudinal direction of the base material and is rectangular, for example. The “non-pasting area” indicates an area in the unit area where the connection film is not pasted to the electronic component, e.g., a margin where the connection film does not exist.

Examples of the first electronic component may include those in which the mounting surface includes a plurality of protrusions and terminal rows provided on the protrusions, those in which a plurality of terminal rows are provided on a flat mounting surface, and those in which a central portion of the mounting surface has a recess and terminal rows are provided on the peripheral portion of the mounting surface. An example of the first electronic component having a recess in a central portion of a mounting surface has, for example, a rectangular mounting surface, and the mounting surface has terminal rows on two opposing sides of the peripheral edge of the recess, two adjacent sides (L-shape) of the recess, or three sides (rectangular U-shape, curved U-shape, or C-shape) of the peripheral edge of the recess. The terminal rows may be located on the entire periphery of the peripheral edge. The peripheral edges of the recess and the terminal rows may be formed only in parallel or perpendicular, but the present invention is not limited to these, and they are appropriately adjusted according to the object. Thus, the shape of the unit area of the connection film may be appropriately adjusted accordingly.

The shape of the mounting surface may be not only a rectangular shape but also a curved shape, a circular shape, and a polygonal shape, among other shapes. In particular, in a curved shape, printing may be preferred because it is easier than processing after film formation. The mounting surface may have holes where the base material is exposed, apart from the periphery of the shape. The shape of the holes may be not only rectangular, but also curved, circular, or polygonal, for example. These shapes are required when another component is designed in the mounting surface so that it will not be in contact with the connection film. The shape of a mounted component with a mounting surface may or may not be similar to the mounting surface. This can apply to either of the first electronic component and the second electronic component, or both (not shown).

When the first electronic component has a recess in the center of the mounting surface, the film structure may have a non-pasting portion from the periphery of the unit area toward the center of the unit area. This prevents the recess from being filled with gas and reducing the reliability of the connection.

When the unit area of the film structure is rectangular, the non-pasting portion may be formed from the central portion of at least one side of the unit area in the direction of the center of the unit area. This allows mounting a first electronic component having a mounting surface with a terminal row formed on three sides (rectangular U-shaped) of the periphery of the recess.

When the unit area of the film structure is rectangular, the non-pasting portion may be formed in the unit area from the central portion of the width direction of the base material in the length direction of the base material. This allows mounting of a first electronic component having a mounting surface with terminal rows formed on two opposite sides of the periphery of the recess.

In the unit area of the film structure, the film may be a connection film consisting of a pasting portion in a polygonal shape such as a hexagon, an octagon, a dodecagon, and rectangular U-shape, or a curved shape such as a curved U-shape, a C-shape, or a cylindrical shape. The pasting portion of the connection film may have a shape that includes both straight and curved lines. As mentioned above, when taking a complex shape, the pasting portion may be divided rather than continuous. The divided portion can be recognized by the fact that it has the same features as the slit edge. The presence of both the printed edge and the slit edge distinguishes the film from those formed by printing alone.

In the unit area of the film structure, at least a part of the pasting portion should have the same shape as the mounting surface of the first electronic component or the second electronic component. In other words, the pasting portion of the connection film may be, e.g., a rectangular shape, a curved shape, a circular shape, a polygonal shape, or the like in accordance with the shape of the mounting surface, and may be a rectangular U-shape, a curved U-shape, a C-shape, or the like in which a part of the former shapes is missing. By making the shape of the pasting portion of the connection film conform to the outer shape of the mounting surface, it is possible to prevent a part of the connection film from protruding excessively from the mounting surface, thereby improving the workability by facilitating the handling of the electronic component to be mounted, preventing the obstruction of the preceding and subsequent processes, and thus reducing the overall manufacturing cost.

The first electronic component and the second electronic component are not particularly limited and can be appropriately selected according to the purpose. Examples of the first electronic component may include a ceramic substrate, a rigid substrate, a flexible printed circuit (FPC), a glass substrate, a plastic substrate, a resin multilayer substrate, an IC (integrated circuit) module, and an IC chip, among others. Examples of the second electronic component may include a ceramic substrate, a rigid substrate, a flexible printed circuit (FPC), a glass substrate, a plastic substrate, and a resin multilayer substrate, among others.

In a functional module such as a camera module, a ceramic substrate is sometimes used from the viewpoint of excellent electrical insulation and thermal insulation. The ceramic substrate has advantages such as excellent dimensional stability in miniaturized implementation (for example, 1 cm² or less).

The connection film is not particularly limited, and examples thereof may include a film-shaped anisotropic conductive film (ACF) and a film-shaped adhesive non-conductive film (NCF). The curing type of the connection film is not particularly limited, and examples thereof may include a thermosetting type, a photo-curing type, and a photo-thermosetting type. The connection film may be a hot melt type using a thermoplastic resin.

It should be noted that the present technology can be used, for example, in a method of manufacturing any electronic device using electrical connections, such as a semiconductor device (including, in addition to driver ICs, all devices using semiconductor such as optical elements, thermoelectric conversion elements, and photoelectric conversion elements), a display device (monitor, television receiver, and head-mounted display, among others), a portable device (tablet, smartphone, and wearable terminal, among others), a game console, an audio device, an imaging device (one using an image sensor such as a camera module), an electric device to be mounted on a vehicle (mobility device), a medical device, a sensor device (touch sensor, fingerprint authentication, and iris authentication, among others), and a household appliance.

In the following, a method of manufacturing a connection structure for mounting a camera module will be described as a specific example. The method of manufacturing a connection structure shown as a specific example includes a pasting step of pasting a connection film to a camera module, a mounting step of mounting a flexible printed circuit onto the camera module, and a connecting step of connecting terminals of the camera module and terminals of the flexible printed circuit via the connection film.

### Camera Module

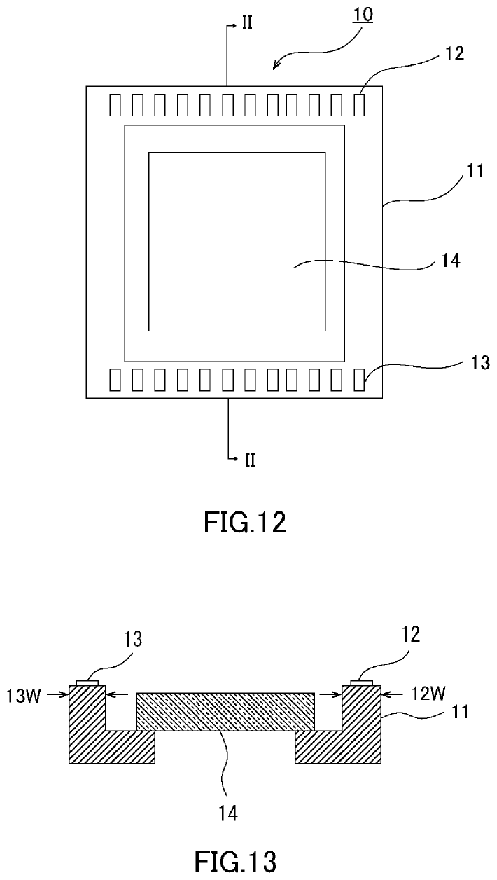

FIG. 12 is a plan view of a mounting surface of a camera module, and FIG. 13 is a cross-sectional view taken along cut line II-II shown in FIG. 12. As shown in FIGS. 12 and 13, the camera module 10 includes a ceramic substrate 11 having a recess (cavity) in a rectangular mounting surface, a first terminal row 12 and a second terminal row 13 formed on two opposite sides of a peripheral edge of the recess on the rectangular mounting surface, and an image sensor 14 accommodated in the recess. In addition, in the cross section taken along the cutting line II-II, the camera module 10 has a mounting surface having a predetermined width 12W on which the first terminal row 12 is formed and a mounting surface having a predetermined width 13W on which the second terminal row 13 is formed.

### Film Structure

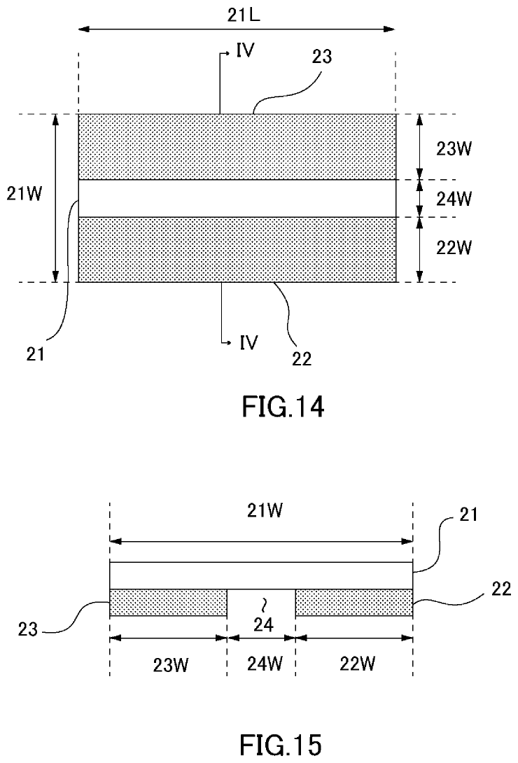

FIG. 14 is a plan view of a unit area of a film structure, and FIG. 15 is a cross-sectional view taken along cut line IV-IV shown in FIG. 14. As shown in FIGS. 14 and 15, the film structure has a tape-shaped base material 21 and connection films 22, 23 formed on the base material 21, and has a rectangular unit area of a predetermined length 21L in the length direction of the base material 21 and a predetermined width 21W in the width direction of the base material 21 in plan view. The film structure 20 has a margin 24 which is a non-pasting portion in the unit area, formed from the central portion of the width direction and extended in the length direction of the base material 21 of the base material 21. The margin 24 can be formed, e.g., by masking the central portion of the width direction of the base material 21 over the length direction of the base material 21 in screen printing. That is, in the film structure 20, a non-pasting portion in the unit area is formed from the central portion in the width direction of the base material and extended in the length direction of the base material, and the connection film 22 of the predetermined width 22W and the connection film 23 of the predetermined width 23W are formed in the length direction of the base material 21 separately so as to correspond with the first terminal row 12 and the second terminal row 13 of the ceramic substrate 11.

The width 22W of the connection film 22 and the width 23W of the connection film 23 may be narrower than, the same as, or wider than the width 12W of the mounting surface of the first terminal row 12 and the width 13W of the mounting surface of the second terminal row 13, respectively.

Setting the width of the connection film to be narrower than the width of the mounting surface of the terminal row can suppress excessive protrusion of the resin of the connection film from the film connection body. As a result, it is possible to avoid contact of the excessively protruded resin with the camera module and other mounted components, thereby improving the workability of assembly.

### Pasting Step

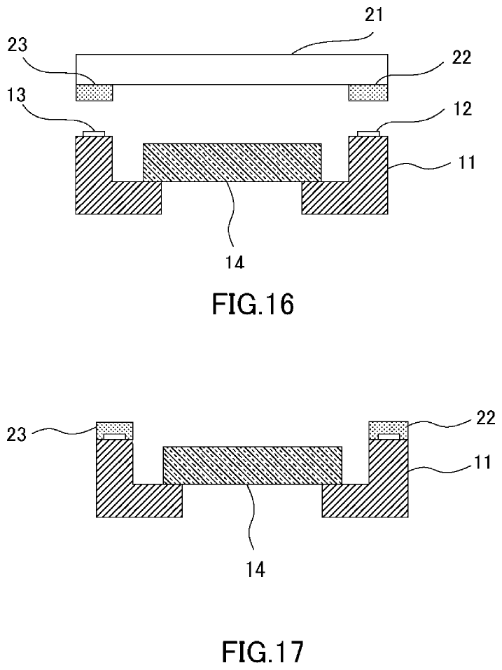

FIG. 16 is a cross-sectional view illustrating an pasting step of pasting a connection film to a camera module, and FIG. 17 is a cross-sectional view of a state in which a base material is peeled off from a connection film in the pasting step. As shown in FIGS. 16 and 17, in the pasting step, the connection films 22, 23 of the unit area of the film structure 20 are transferred to the camera module 10. For example, by using a pasting device, the connection films 22, 23 of the unit area are pressed from the base material side of the film structure and simultaneously pasted on the mounting surfaces of the camera module 10 placed on a stage. The film structure from which the connection films 22, 23 are transferred is wound away as a base material only.

### Mounting Step

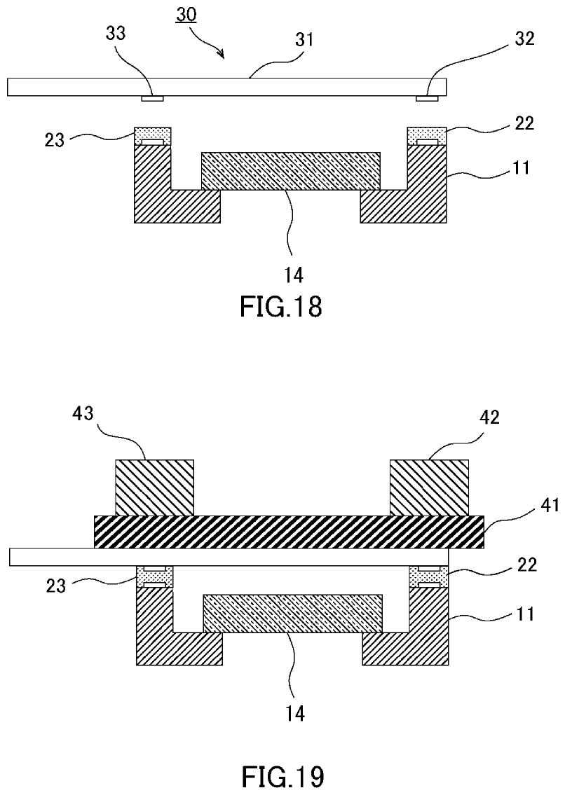

FIG. 18 is a cross-sectional view of a mounting step in which a flexible printed circuit is mounted on a camera module. As shown in FIG. 18, the flexible printed circuit 30 has a first terminal row 32 and a second terminal row 33 on a base material 31 corresponding to the first terminal row 12 and the second terminal row 13 of the camera module 10. In the mounting step, the first terminal row 32 and the second terminal row 33 of the flexible printed circuit 30 are aligned with the first terminal row 12 and the second terminal row 13 of the camera module 10, and the flexible printed circuit 30 is mounted onto the camera module 10.

### Connecting Step

FIG. 19 is a cross-sectional view of a connection process in which terminals of a camera module are connected to terminals of a flexible printed circuit via a connection film. As shown in FIG. 19, in the connecting step, for example, via a cushioning material 41, the first terminal row 12 of the camera module 10 and the first terminal row 32 of the flexible printed circuit 31 are pressed together by the crimping tool 42, and the second terminal row 13 of the camera module 10 and the second terminal row 33 of the flexible printed circuit 30 are pressed together by the crimping tool 43. Further, according to the curing type of the connection film, heating, light irradiation, or the like is performed to cure the connection film.

### Camera Module Mounted Body

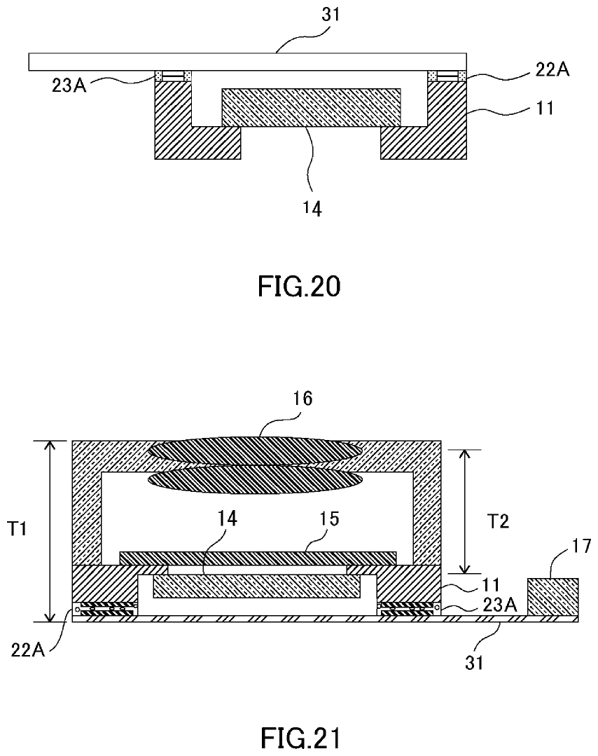

FIG. 20 is a cross-sectional view of a connection structure in which a camera module is mounted. As shown in FIG. 20, in the connection structure in which the camera module 10 is mounted, the first terminal row 12 of the camera module 10 and the first terminal row 32 of the flexible printed circuit 30 are connected via a cured film 22A formed by curing the connection film 22. The second terminal row 13 of the camera module 10 and the second terminal row 33 of the flexible printed circuit 30 are connected via a cured film 23A formed by curing the connection film 23. In the case of a hot-melt type connection film, the cured film 23 is a cured film of the hot-melt type connection film.

FIG. 21 is a cross-sectional view of a configuration example of a connection structure in which a camera module is mounted. The same parts as those shown in FIGS. 12 to 20 are denoted by the same reference numerals, and description thereof is omitted. As shown in FIG. 21, the connection structure includes: a camera module 10 having a first terminal row 12 and a second terminal row 13; a flexible printed circuit 30 having a first terminal row 32 and a second terminal row 33; a cured film 22A provided between the first terminal row 12 and the first terminal row 32 and formed by curing a connection film 22; and a cured film 23A provided between the second terminal row 13 and the second terminal row 33 and formed by curing the connection film 23. The connection structure has a protective glass 15 fixed on the ceramic substrate 11 and a lens 16 arranged above the image sensor 14 and fitted in a housing. In addition to the camera module mounting portion, a camera module drive IC 17 may be mounted on the flexible printed circuit 30.

According to the connection structure having such a configuration, although it is difficult to reduce the optical distance T2 between the image sensor 14 and the lens 16, it is possible to reduce the distance T1 between the lens 16 and the flexible printed circuit 30, thereby making it possible to reduce the entire thickness. In the rectangular mounting surface of the connection structure, the two opposite sides of the peripheral edge of the recess of the ceramic substrate 11 are bonded by the cured film 22A and the cured film 23A, and parts of the other two sides are not bonded. Therefore, the recess of the ceramic substrate 11 is not sealed by the base material 31 of the flexible printed circuit 30, thereby preventing the flexible printed circuit 30 from swelling due to the influence of gas.

### Examples

### 4-1. First Examples

The first example of this technology is described below. The following anisotropic conductive paste, substrate for evaluation, and FPC for evaluation were prepared.

### Anisotropic Conductive Paste

An anisotropic conductive adhesive composition was prepared by introducing 5 parts by mass of resin core conductive particles (Ni (undercoat)/Au (surface) plating, resin core) having an average particle diameter of 20 μm and 95 parts by mass of an insulating binder into a planetary type stirring device (product name: Awatori Rentaro (ARE), manufactured by THINKY) and stirring them for 1 minute.

The insulating binder was prepared by mixing 47 parts by mass of phenoxy resin (product name: YP-50, manufactured by NSCC Epoxy Manufacturing), 3 parts by mass of monofunctional monomer (product name: M-5300, manufactured by TOAGOSEI), 25 parts by mass of urethane resin (product name: UR-1400, manufactured by Toyobo), 15 parts by mass of rubber component (product name: SG80H, manufactured by Nagase ChemteX), 2 parts by mass of silane coupling agent (product name: A-187, manufactured by Momentive Performance Materials Japan), and 3 parts by mass of organic peroxide (product name: NiperBW, manufactured by Nichiyu Corporation), into a mixed solution of ethyl acetate and toluene so that the solid content was 50% by mass.

### Substrate for Evaluation

Alumina ceramic substrate, substrate thickness: 0.4 mm, width: 6.0 mm, mounting surface of terminal rows: 1.0 mm×6.0 mm, tungsten wiring, line: space=100 μm/100 μm, terminal height 10 μm, line: space=100 μm/100 μm, with cavity structure, terminal rows exist on two opposite sides

### FPC for Evaluation

Copper wiring, line: space=100 μm/100 μm, terminal height=12 μm, polyimide film thickness: 25 μm

### Example 1

An individual-piece-shaped anisotropic conductive film was prepared by screen printing using a screen mask with a shape that matches the mounting surface of the substrate for evaluation ((in the unit area (21W, 21L: 6.0 mm) shown in FIGS. 14, 15), the connection film 22, 23 portions (22W, 23W: 1.2 mm) were used as the portions where the paste passes through) to apply anisotropic conductive paste on a mold release film and dry the paste. After pasting the individual-piece-shaped anisotropic conductive film to a substrate for evaluation, an FPC for evaluation was mounted and thermocompression-bonded (temperature: 140° C., pressure: 1 MPa, time: 6 sec) to prepare a connection structure.

According to microscopic observation of the indentation of conductive particles on the terminal from the FPC side of the connection structure, the number of conductive particles trapped per terminal (connection area: 200,000 μm²) was 25.5. The productivity of the individual-piece-shaped anisotropic conductive film was excellent. Linear-shaped anisotropic conductive films with a width of about 100 μm could also be manufactured.

### Comparative Example 1

Anisotropic conductive paste was applied to the entire surface of a mold release film with a coater and dried to form an anisotropic conductive film. An individual-piece-shaped anisotropic conductive film was prepared by half-cutting the anisotropic conductive film along the shape matching the mounting surface of the substrate for evaluation (the connection film 22, 23 portions (22W, 23W: 1.2 mm) in the unit area (21W, 21L: 6.0 mm) shown in FIGS. 14 and 15), and then removing the unnecessary portions. After laminating the individual-piece-shaped anisotropic conductive film to the substrate for evaluation, an FPC for evaluation was mounted and thermocompression-bonded (temperature: 140° C., pressure: 1 MPa, time: 6 sec) to prepare a connection structure.

According to microscopic observation of the indentation of conductive particles on the terminal from the FPC side of the connection structure, the number of conductive particles trapped per terminal (connection area: 200,000 μm²) was 26.1. Compared to the example, the productivity of individual-piece-shaped anisotropic connection film was poor in terms of the number of processes and material loss due to the need to remove unnecessary parts. In addition, when linear-shaped anisotropic conductive film with a width of about 100 μm was fabricated, necessary portions were also peeled off from the mold release film when unnecessary portions were removed.

### Reference Example 1

Anisotropic conductive paste was applied on a substrate for evaluation by screen printing using a screen mask with a shape matching the mounting surface of the substrate for evaluation ((in the unit area (21W, 21L: 6.0 mm) shown in FIGS. 14, 15), the connection film 22, 23 portions (22W, 23W: 1.2 mm) were used as the portions where the paste passes through). An FPC for evaluation was mounted on this and thermocompression bonded (temperature: 140° C., pressure: 1 MPa, time: 6 sec) to prepare a connection structure.

According to microscopic observation of the indentation of conductive particles on the terminal from the FPC side of the connection structure, the number of conductive particles trapped per terminal (connection area: 200,000 μm²) was 15.2. This is believed to be due to conductive particles entering between the wires during application, resulting in an uneven particle density and a low number of particles present on the terminals.

Table 1 shows the evaluation results of Example 1, Comparative Example 1, and Reference Example 1.

TABLE 1

| | EX. 1 | COMP. 1 | REF. 1 |
|---|---|---|---|
| forming method | screen printing | harf cutting | screen printing |
| formed surface | mold release | mold release | substrate |
| | film | film | |
| trapped conductive | 25.5 | 26.1 | 15.2 |
| particle number | | | |
| productivity | good | bad | — |

### 4-2. Second Examples

In the second examples, a slitter was used to produce a stripe-patterned anisotropic conductive film with a width narrower than the slit width, and the shape of the anisotropic conductive film was evaluated. The anisotropic conductive paste used was the same as in the first examples, and a slitter with a lower limit of slit width of 0.4 mm was used.

### Evaluation

The stripe-patterned anisotropic conductive film was observed under a microscope and evaluated using the following criteria. Here, “floating” refers to the state in which the anisotropic conductive film is separated from the mold release film, and “wrinkling” refers to the state in which lines due to, e.g., crimping are observed on the anisotropic conductive film.

A: no floating and wrinkling can be found on all anisotropic conductive films.

B: either floating or wrinkling can be found in some of the anisotropic conductive films.

C: stripe-patterned anisotropic conductive film cannot be manufactured.

### Example 11

Using a screen mask with multiple stripe-patterned apertures of 0.1 mm line width, anisotropic conductive paste was applied to a mold release film by screen printing and dried to form a stripe-patterned anisotropic conductive film with a row of multiple rectangles of 0.1 mm line width, 150 mm length, and 25 μm thickness on the mold release film.

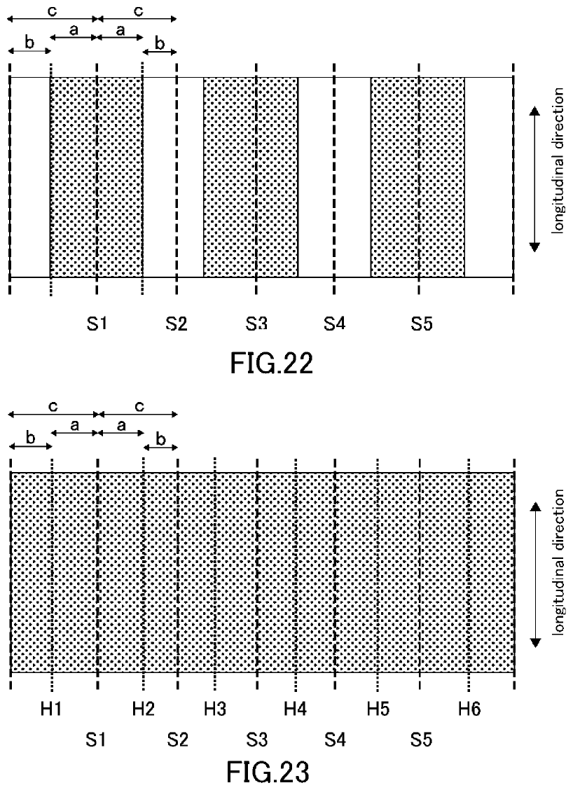

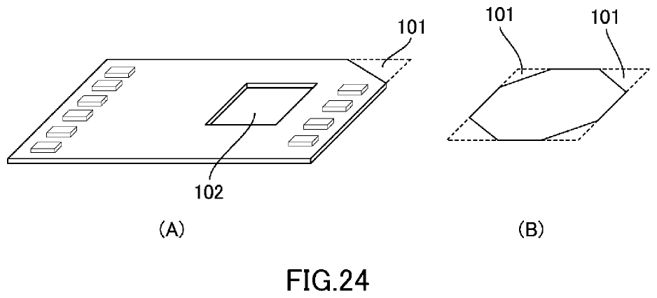

FIG. 22 is a plan view illustrating the manufacturing of an anisotropic conductive film in the example. As shown in FIG. 22, in Example 11, a stripe-patterned anisotropic conductive film was formed by providing a mold release film portion having a width b serving as a margin of 0.35 mm on both sides of the line width (a+a) 0.1 mm in the width direction. Then, the center of the line width (a+a) and the center of the margin width (b+b) are slit at S1 to S5 with a slit width of 0.4 mm to form an anisotropic conductive film with a width a of 0.05 mm and a length of 150 mm. This anisotropic conductive film was formed five times. Although floating was observed in some of the anisotropic conductive films, anisotropic conductive films with a width of 0.05 mm could be formed in a single slit process (evaluated as B).

### Example 12

Using a screen mask with multiple stripe-patterned apertures of 0.2 mm in line width, anisotropic conductive paste was applied to a mold release film by screen printing and dried to form a stripe-patterned anisotropic conductive film with a row of multiple rectangles of 0.2 mm line width, 150 mm length, and 25 μm thickness on the mold release film.

As shown in FIG. 22, in Example 12, a stripe-patterned anisotropic conductive film was formed by providing a mold release film portion having a width b serving as a margin of 0.3 mm on both sides of the line width (a+a) 0.2 mm in the width direction. Then, the center of the line width (a+a) and the center of the margin width (b+b) are slit at S1 to S5 with a slit width of 0.4 mm to form an anisotropic conductive film with a width of 0.1 mm and a length of 150 mm. This anisotropic conductive film was formed five times. All of the anisotropic conductive films were able to be formed with a width of 0.1 mm in a single slit process without any floating or wrinkling (evaluated as A).

### Example 13

Using a screen mask with multiple stripe-patterned apertures of 0.32 mm line width, anisotropic conductive paste was applied to a mold release film by screen printing and dried to form a stripe-patterned anisotropic conductive film with a row of multiple rectangles of 0.32 mm line width, 150 mm length, and 25 μm thickness on the mold release film.

As shown in FIG. 22, in Example 13, a stripe-patterned anisotropic conductive film was formed by providing a mold release film portion having a width b serving as a margin of 0.24 mm on both sides of the line width (a+a) 0.32 mm in the width direction. Then, the center of the line width (a+a) and the center of the margin width (b+b) are slit at S1 to S5 with a slit width of 0.4 mm to form an anisotropic conductive film with a width of 0.16 mm and a length of 150 mm. This anisotropic conductive film was formed five times. All of the anisotropic conductive films could be formed with a width of 0.16 mm in a single slit process without any floating or wrinkling (evaluated as A).

### Example 14

Using a screen mask with multiple stripe-patterned apertures of 0.4 mm line width, anisotropic conductive paste was applied to a mold release film by screen printing and dried to form a stripe-patterned anisotropic conductive film with a row of multiple rectangles of 0.4 mm line width, 150 mm length, and 25 μm thickness on the mold release film.

As shown in FIG. 22, in Example 14, a stripe-patterned anisotropic conductive film was formed by providing a mold release film portion having a width b serving as a margin of 0.2 mm on both sides of the line width (a+a) 0.4 mm in the width direction. Then, the center of the line width (a+a) and the center of the margin width (b+b) are slit at S1 to S5 with a slit width of 0.4 mm to form an anisotropic conductive film with a width a of 0.2 mm and a length of 150 mm. This anisotropic conductive film was formed five times. All of the anisotropic conductive films could be formed with a width of 0.2 mm in a single slit process without any floating or wrinkling (evaluated as A).

### Example 15

Using a screen mask with multiple stripe-patterned apertures of 0.48 mm line width, anisotropic conductive paste was applied to a mold release film by screen printing and dried to form a stripe-patterned anisotropic conductive film with a row of multiple rectangles of 0.48 mm line width, 150 mm length, and 25 μm thickness on the mold release film.

As shown in FIG. 22, in Example 15, a stripe-patterned anisotropic conductive film was formed by providing a mold release film portion having a width b serving as a margin of 0.16 mm on both sides of the line width (a+a) 0.48 mm in the width direction. Then, the center of the line width (a+a) and the center of the margin width (b+b) are slit at S1 to S5 with a slit width of 0.4 mm to form an anisotropic conductive film with a width a of 0.24 mm and a length of 150 mm. This anisotropic conductive film was formed five times. All of the anisotropic conductive films could be formed with a width of 0.24 mm in a single slit process without any floating or wrinkling (evaluated as A).

### Example 16

Using a screen mask with multiple stripe-patterned apertures of 0.6 mm in line width, anisotropic conductive paste was applied to a mold release film by screen printing and dried to form a stripe-patterned anisotropic conductive film with a row of multiple rectangles of 0.6 mm line width, 150 mm length, and 25 μm thickness on the mold release film.

As shown in FIG. 22, in Example 16, a stripe-patterned anisotropic conductive film was formed by providing a mold release film portion having a width b serving as a margin of 0.1 mm on both sides of the line width (a+a) 0.6 mm in the width direction. Then, with a slit width of 0.4 mm, the center of the line width (a+a) and the center of the margin width (b+b) are slit at S1 to S5 to form an anisotropic conductive film with a width of 0.3 mm and a length of 150 mm. This anisotropic conductive film was formed five times. Although floating or wrinkling was observed in some of the anisotropic conductive films, anisotropic conductive films with a width of 0.3 mm could be formed in a single slit process (evaluated as B).

### Conventional Example

FIG. 23 is a plan view of the manufacturing of an anisotropic conductive film in a conventional example. Anisotropic conductive paste was applied to the entire surface of a mold release film with a coater and dried to form an anisotropic conductive film. Then, as shown in FIG. 23, five attempts were made to form an anisotropic conductive film with a width of 0.1 mm and a length of 150 mm by making half-cuts H1 to H6 with a width a of 0.1 mm, the center of the line width (a+a) and the center of the margin width (b+b) are slit at S1 to S5 with a slit width of 0.4 mm, and removing the anisotropic conductive film with a width b of 0.3 mm. As a result, it was not possible to form the film in a single slit process as in the examples, and floating occurred when removing the unnecessary portions, so that stripe-patterned anisotropic conductive films could not be formed (evaluated as C).

Table 2 shows the evaluation results of Examples 11 to 16 and the conventional example.

TABLE 2

| | | | | | | | Conventional |
|---|---|---|---|---|---|---|---|
| | EX. 11 | EX. 12 | EX. 13 | EX. 14 | EX. 15 | EX. 16 | Example |
| manufacturing method | print + slit | | | | | | harf cut + slit |
| film width a [μm] | 0.05 | 0.1 | 0.16 | 0.2 | 0.24 | 0.3 | 0.1 |
| margin width b [μm] | 0.35 | 0.3 | 0.24 | 0.2 | 0.16 | 0.1 | 0.3 |
| slit width c [μm] | 0.4 | 0.4 | 0.4 | 0.4 | 0.4 | 0.4 | 0.4 |
| a/c | 0.125 | 0.25 | 0.4 | 0.5 | 0.6 | 0.75 | 0.25 |
| evaluation | B | A | A | A | A | B | C |

In the conventional example, stripe-patterned anisotropic conductive films could not be formed in a single slit process as in the examples, and floating occurred when removing unnecessary portions, making it impossible to form stripe-patterned anisotropic conductive films. On the other hand, in Examples 11 to 16, the ratio of the width a of the anisotropic conductive film to the slit width c is between 0.125 and 0.75, and thus anisotropic conductive films with a width narrower than the slit width could be formed in a single slit process after printing. In Examples 12 to 15, the ratio of the width a of the anisotropic conductive film to the slit width c was between 0.25 and 0.6, thereby preventing floating and wrinkling. Although anisotropic conductive films were formed and evaluated in the above examples, it can be inferred that the same effect can be expected for adhesive films and conductive films.

### REFERENCE SIGNS LIST

1 mold release film, 2 adhesive, 3 screen mask, 4 connection film, 5 substrate, 10 camera module, 11 ceramic substrate, 12 first terminal row, 13 second terminal row, 14 image sensor, 15 protective glass, 16 lens, 17 camera module driver IC, 20 winding core, 21 base material, 22 connection film, 23 connection film, 24 margin, 30 flexible printed circuit, 31 base material, 32 first terminal row, 33 second terminal row, 41 cushioning material, 42 crimping tool, 43 crimping tool, 51 mold release film, 52 connection film, 53 mold release film, 54 connection film, 55 printed side, 56 slit side, 57 mold release film, 58 mold release film, 59 to 66 connection film, 101 corner, 102 recess

1. A method for manufacturing a connection film comprising: printing an adhesive in a predetermined shape on a mold release film; and forming a connection film of a predetermined shape on the mold release film.

2. The method for manufacturing a connection film according to claim 1, wherein a plurality of connection films of the predetermined shape are formed in the width direction of the mold release film, the mold release film is cut in the longitudinal direction at a predetermined width, a plurality of mold release films of the predetermined width are connected in the longitudinal direction, and the connected mold release films of the predetermined width are wound around a winding core.

3. The method for manufacturing a connection film according to claim 2, wherein the connection film of the predetermined shape is cut when the mold release film is cut in the longitudinal direction at the predetermined width.

4. The method for manufacturing a connection film according to claim 2, wherein the connection film of the predetermined shape is not cut when the mold release film is cut in the longitudinal direction at the predetermined width.

5. The method for manufacturing a connection film according to claim 1, wherein
the adhesive contains conductive particles, and
a conductive film of a predetermined shape is formed on the mold release film.

6. The method for manufacturing a connection film according to claim 1, wherein
the adhesive contains conductive particles, and
an anisotropic conductive film of a predetermined shape is formed on the mold release film.

7. The method for manufacturing a connection film according to claim 1, further comprising:
placing conductive particles at predetermined positions on the connection film of the predetermined shape; and
forming an anisotropic conductive film of a predetermined shape on the mold release film.

8. The method for manufacturing a connection film according to claim 1, wherein the printing is screen printing or inkjet printing.

9. The method for manufacturing a connection film according to claim 1, further comprising: providing a margin in the width direction of the mold release film to form a rectangular connection film in the longitudinal direction, and cutting the mold release film in the longitudinal direction at a predetermined width.

10. The method for manufacturing a connection film according to claim 9, wherein the mold release film is cut in the longitudinal direction so that one end of the predetermined width is the margin and the other end is the connection film.

11. The method for manufacturing a connection film according to claim 10, wherein the mold release film is cut so that the width of the connection film relative to the predetermined width is between 0.125 and 0.75.

12. The method for manufacturing a connection film according to claim 9, wherein the predetermined width is less than 0.5 mm.

13. A connection film manufactured by the manufacturing method according to claim 1.

14. A connection structure, comprising:
a first electronic component having a first terminal;
a second electronic component having a second terminal; and
a cured film formed by curing the connection film manufactured by the manufacturing method according to claim 1, wherein
the first terminal and the second terminal are connected by the cured film.

15. A method for manufacturing a connection structure comprising: connecting a terminal of a first electronic component to a terminal of a second electronic component via a connection film manufactured by the manufacturing method according to claim 1.

16. A film structure, comprising:
a mold release film; and
a connection film that an adhesive is printed in a predetermined shape on the mold release film.

17. The film structure according to claim 16, wherein the mold release film and the connection film having a predetermined shape have a cut surface on at least one side in the width direction.

18. The film structure according to claim 16, wherein the mold release film has a cut surface on at least one side in the width direction.

19. The film structure according to claim 16, wherein the mold release film has a predetermined width, the width of the connection film with respect to the predetermined width is 0.125 or more and 0.75 or less.

20. The film structure according to claim 19, wherein the predetermined width is less than 0.5 mm.

21. A connection film, comprising:
an adhesive being printed in a predetermined shape on the mold release film.

22. The connection film according to claim 21, wherein the connection film has one side that coincides with a side of the mold release film, and has a width that is smaller than the width of the mold release film.

23. The connection film according to claim 21, wherein the connection film is accommodated inside the mold release film, and both ends of the mold release film are exposed.

24. The connection film according to claim 21, wherein two connection films are formed in the width direction of the release-treated film, the connection film has one side that coincides with a side of the mold release film, and mold release film is exposed between the two connection films.
